(19) United States
(12) Patent Application Publication
(10) Pub. No.: US 2009/0267210 A1
(43) Pub. Date: Oct. 29, 2009

(54) INTEGRATED CIRCUIT PACKAGE AND MANUFACTURING METHOD THEREOF

(76) Inventors: Yao-Kai CHUANG, Kaohsiung City (TW); Chien Liu, Kaohsiung City (TW); Chih-Ming Chung, Dashe Township (TW); Chao-Cheng Liu, Gangshan Township (TW)

Correspondence Address: Muncy, Geissler, Olds & Lowe, PLLC, P.O. BOX 1364, FAIRFAX, VA, 22038-1364, US

(21) Appl. No.: 12/428,762

(22) Filed: Apr. 23, 2009

(30) Foreign Application Priority Data
Apr. 29, 2008 (TW) 97115779

(51) Int. Cl. H01L 23/498; H01L 21/50

(52) U.S. Cl. 257/686; 438/107; 257/738; 257/777; 257/E23.068; 257/E21.499

(57) ABSTRACT

An integrated circuit package and a manufacturing method thereof are provided. The package includes a die pad, a plurality of first and second contact pads, a first die, a second die and a molding compound. The contact pads adjacent to at least one side of the die pad are arranged along an inner row and an outer row with respect to the die pad. The first die is fixed on the first die and electrically connected to the first contact pads by wire-bonding. The second die is fixed on the first die and electrically connected to the second contact pads by wire-bonding. The molding compound covers the second die, the first die, the die pad, the first contact pads and the second contact pads. The bottoms of the die pad, the first contact pads and the second contact pads are exposed at the bottom surface of the molding compound.

This application claims the benefit of Taiwan application Serial No. 97115779, filed Apr. 29, 2008, the subject matter of which is incorporated herein by reference.

### BACKGROUND OF THE INVENTION

1. Field of the Invention

The invention relates in general to an integrated circuit package and a manufacturing method thereof, and more particularly to an integrated circuit package with stacked dies and a manufacturing method thereof.

2. Description of the Related Art

Currently, the design and development of electronic products are directed towards slimness, compactness, lightweight, multi-function and high speed. With the input of resources in the research and development in the electronic packaging industry, various packaging technologies and products are provided one after another. In addition to supporting the development of electronic products, the electronic packaging industry is also aimed at increasing the input/output (I/O) density of various package products, reducing manufacturing cost and increasing manufacturing efficiency so as to enhance product competitiveness.

Of various packaging technologies and products, quad-flat non-leaded (QFN) packaging technology has become a focus in the application and development of the packaging ethnology. QFN adopts micro lead-frame and has similar advantages with chip size package (CSP), that is, there is no need to extend the pins from the four sides, hence saving a large amount of space. QFN package product directly uses the contact pads exposed at the bottom as the pins instead of using the older balls as the pins.

Besides, QFN package product has excellent heat radiation and electrical properties. In terms of heat radiation, the QFN package product provides more paths for radiating the heat by partly exposing the die pad from the bottom. In terms of electrical properties, the contact pads of the QFN package product have shorter conductive path, and smaller self-inductance coefficient, lower internal layout resistance, smaller parasitic inductance and capacitance. Therefore, the application of the QFN packaging technology and products has gained great popularity in recent years.

### SUMMARY OF THE INVENTION

The invention is directed to an integrated circuit package having stacked die structure. Apart from having excellent heat radiation and electrical properties, the package of the invention has more input/output solder pads, provides more functions but occupies smaller space. Besides, in the manufacturing method, the die pad, the first contact pads, the second contact pads being electrically isolated from each other are formed by etching the bottom surface of the metal plate after the molding compound is formed. Thus, the manufacturing process is made simpler, and the manufacturing cost is further reduced.

According to a first aspect of the present invention, an integrated circuit package is provided. The package includes a die pad, a plurality of first and second contact pads, a first die, a second die and a molding compound. The contact pads adjacent to at least one side of the die pad are divided into two rows arranged along at least one side of the die pad, wherein the first contact pads are disposed in the inner row, and the second contact pads are disposed in the outer row. The die pad, the first contact pads and the second contact pads are electrically isolated from each other. The first die is fixed on the first die and electrically connected to the first contact pads by wire-bonding. The second die is fixed on the first die and electrically connected to the second contact pads by wire-bonding. The molding compound covers the second die, the first die, the die pad, the first contact pads and the second contact pads. The bottom of the die pad, the bottom of the first contact pads and the bottom of the second contact pads are exposed at the bottom surface of the molding compound.

According to a second aspect of the present invention, a method of manufacturing integrated circuit package is provided. The method includes the following steps. Firstly, a top surface of a metal plate is patterned so as to define a first region, a plurality of second regions and a plurality of third regions on the top surface. The second regions and the third regions both adjacent to at least one side of the first region are divided into two rows arranged along at least one side of the first region, wherein the second regions are disposed in the inner row, and the third regions are disposed in the outer row. Next, a first die is fixed on a metal plate in the first region. Then, a second die is fixed on the first die. Next, the first die is electrically connected to the metal plate in the second regions by wire-bonding. Then, the second die is electrically connected to the metal plate in the third regions by wire-bonding. Next, a molding compound is formed on a top surface covers the second die, the first die and the top surface of the metal plate. After that, at least a part of the bottom surface of the metal plate is etched so that the metal plate respectively form a die pad, a plurality of first contact pads and a plurality of second contact pad in the first region, the second regions and the third regions, wherein the die pad, the first contact pads and the second contact pad are electrically isolated from each other.

The invention will become apparent from the following detailed description of the preferred but non-limiting embodiments. The following description is made with reference to the accompanying drawings.

### BRIEF DESCRIPTION OF THE DRAWINGS

FIG. 1 shows an upward view of an integrated circuit package according to a first embodiment of the invention;

FIG. 2 shows a side view of the integrated circuit package according to the first embodiment of the invention;

FIG. 3 shows a side view of an integrated circuit package according to a second embodiment of the invention;

FIGS. 4A˜4E respectively show the method of the manufacturing of the integrated circuit package of the first embodiment;

FIGS. 5A˜5F respectively show the method of the manufacturing of the integrated circuit package of the first embodiment; and

FIGS. 6A˜6F respectively show the method of the manufacturing of the integrated circuit package of the second embodiment.

### DETAILED DESCRIPTION OF THE INVENTION

An integrated circuit package with stacked dies providing package product with more functions is disclosed in the invention. The package at least includes a first die and a plurality of first contact pads electrically connected to the first die, and a second die and a plurality of second contact pads electrically connected to the second die. The first die is fixed on a die pad. The second die is fixed on the first die. The first contact pads and the second contact pads both adjacent to at least one side of the die pad are divided into two rows and arranged along at least one side of the die pad, wherein the first contact pads are disposed in the inner row, and the second contact pads are disposed in the outer row.

In the first embodiment and the second embodiment below, the integrated circuit package is exemplified by a package structure formed by way of backside etching. However, the structures disclosed in the following embodiments are for exemplification only, not for limiting the scope of protection of the invention. In practical application, the package structure can be adapted or adjusted to fit actual needs. Moreover, any package structures applicable to the technology of the invention are within the scope of protection of the invention, and secondary elements are omitted in the embodiments for highlighting the technical features of the invention.

### First Embodiment

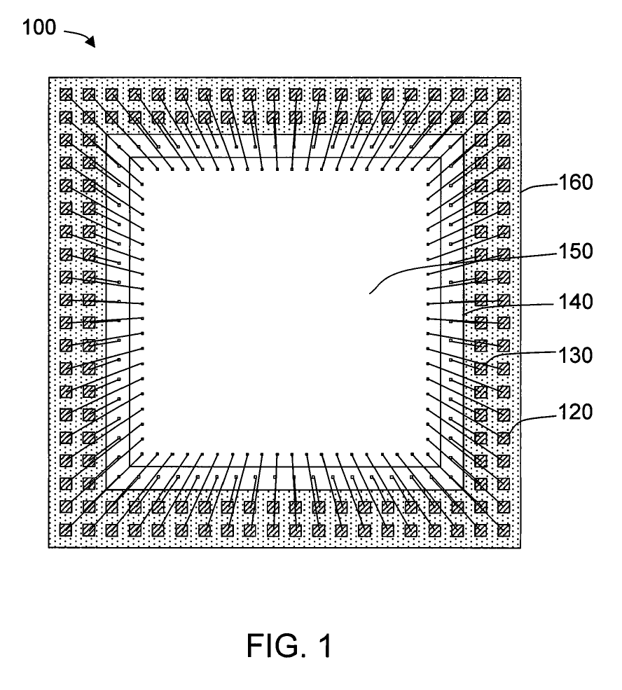

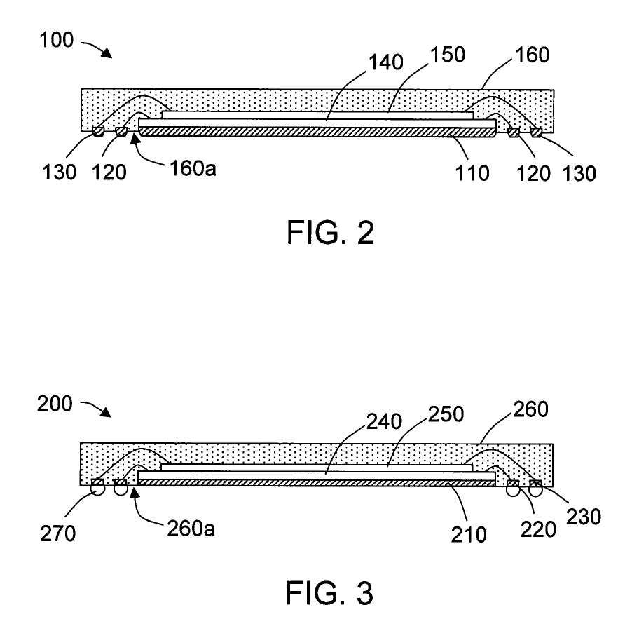

Referring to FIG. 1 and FIG. 2. FIG. 1 shows an upward view of an integrated circuit package according to a first embodiment of the invention. FIG. 2 shows a side view of the integrated circuit package according to the first embodiment of the invention. The package 100 includes a die pad 110, a plurality of first contact pads 120, a plurality of second contact pads 130, a first die 140, a second die 150 and a molding compound 160.

In the present embodiment of the invention, the die pad 110 is surrounded by the first contact pads 120 and the second contact pads 130. The first contact pads 120 and the second contact pads 130 are divided into two rows arranged along one side of the die pad 110. The first contact pads 120 are disposed in the inner row, and the second contact pads 130 are disposed in the outer row. The die pad 110, the first contact pads 120 and the second contact pads 130 are electrically isolated from each other. The first die 140 is fixed on the first die 110 and is electrically connected to the first contact pads 120 by wire-bonding. The second die 150 is fixed on the first die 140 and is electrically connected to the second contact pads 130 by wire-bonding. The molding compound 160 covers the second die 150, the first die 140, the die pad 110, the first contact pads 120 and the second contact pads 130. The bottom of the die pad 110, the bottom of the first contact pads 120 and the bottom of the second contact pads 130 are protruded from the bottom surface 160a of the molding compound 160 and used as the pins of the package. Preferably, an outer side of the second contact pads 130 is not aligned with a side wall of the molding compound 160, such that the second contact pads 130 are indented into the region surrounded by the side wall of the molding compound 160.

### Second Embodiment

The second embodiment is similar to the first embodiment, and the difference lies in the design of the pins of the package. In the second embodiment, solder balls are disposed on the bottom of each contact pad and used as the pins of the package. Referring to FIG. 3, a side view of an integrated circuit package according to a second embodiment of the invention is shown. Likewise, the molding compound 260 of the second embodiment also covers the second die 250, the first die 240, the die pad 210, the first contact pads 220 and the second contact pads 230. However, the bottom of the die pad 210, the bottom of the first contact pads 220 and the bottom of the second contact pads 230 are substantially aligned with the bottom surface 260a of the molding compound 260. The package 200 further includes a plurality of solder balls 270 disposed on the bottom of the first contact pads 220 and the bottom of the second contact pads 230 and used as the pins of the package.

Manufacturing Method

A method of manufacturing integrated circuit package is disclosed below. However, the steps of the manufacturing method disclosed in the invention are for exemplification only not for limiting the scope of protection of the invention. In practical application, the parameters of manufacturing process and details of the steps are adjusted to fit actual needs.

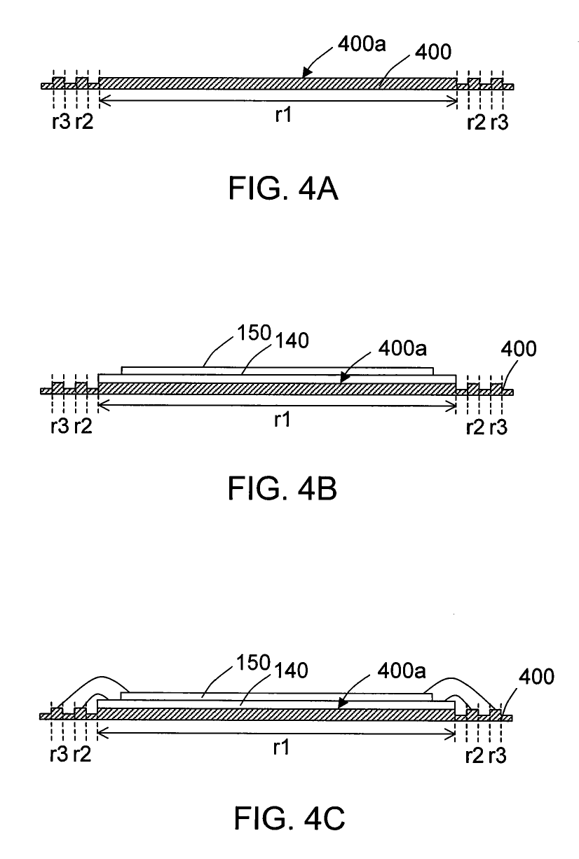

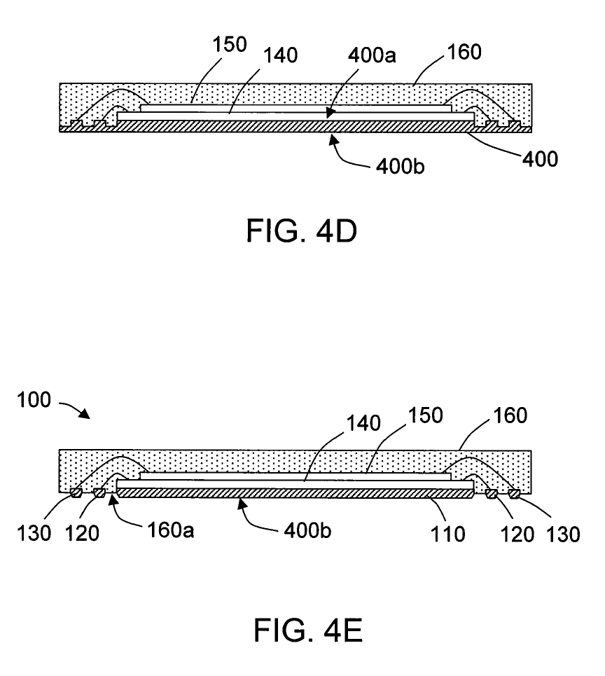

Referring to FIGS. 4A˜4E, the method of the manufacturing of the integrated circuit package of the first embodiment are respectively shown. The manufacturing method, for example, includes the following steps.

Firstly, as indicated in FIG. 4A, a top surface 400a of a metal plate 400 is patterned so as to define a first region r1, a plurality of second regions r2 and a plurality of third regions r3 on the top surface 400a. The second regions r2 and the third regions r3 both adjacent to at least one side of the first region r1 are divided into two rows arranged along one side of the first region r1, wherein the second regions r2 are disposed in the inner row, and the third regions r3 are disposed in the outer row. In the present step, the metal plate 400 is etched according to a first pattern such that the thickness of the part of the patterned metal plate 400 in the first region r1, the second regions r2 and the third regions r3 is larger than the thickness of the metal plate 400 in other regions.

Then, as indicated in FIG. 4B, a first die 140 is fixed on the metal plate 400 of the first region r1, and a second die 150 is fixed on the first die 140. In the step of fixing the first die 140 and the second die 150, normally, an epoxy resin is used for adhering the first die 140 onto the metal plate 400 in the first region r1 and adhering the second die 150 onto the first die 140. After the first die 140 and the second die 150 are fixed, the epoxy resin is solidified.

Then, as indicated in FIG. 4C, the first die 140 is electrically connected to the metal plate 400 in the second regions r2 by wire-bonding, and the second die 150 is electrically connected to the metal plate 400 in the third regions r3 by wire-bonding.

After that, as indicated in FIG. 4D, a molding compound 160 is formed on the top surface of 400a for covering the second die 150, the first die 140 and the top surface 400a of the metal plate 400. In the present step, the molding compound 160 is normally formed from a colloid. After that, the colloid is solidified.

Afterwards, as indicated in FIG. 4E, at least a part of a bottom surface 400a of the metal plate 400 is etched so that the metal plate 400 respectively forms the die pad 110, a plurality of first contact pads 120 and a plurality of second contact pads 130 on the first region r1, the second regions r2 and the third regions r3, wherein the die pad 110, the first contact pads 120 and the second contact pads 130 are electrically isolated from each other. In the present step, the bottom surface 400a of the metal plate 400 is etched according to micro-filming process for example.

Lastly, the metal plate 400 is sawn for forming at least one integrated circuit package 100.

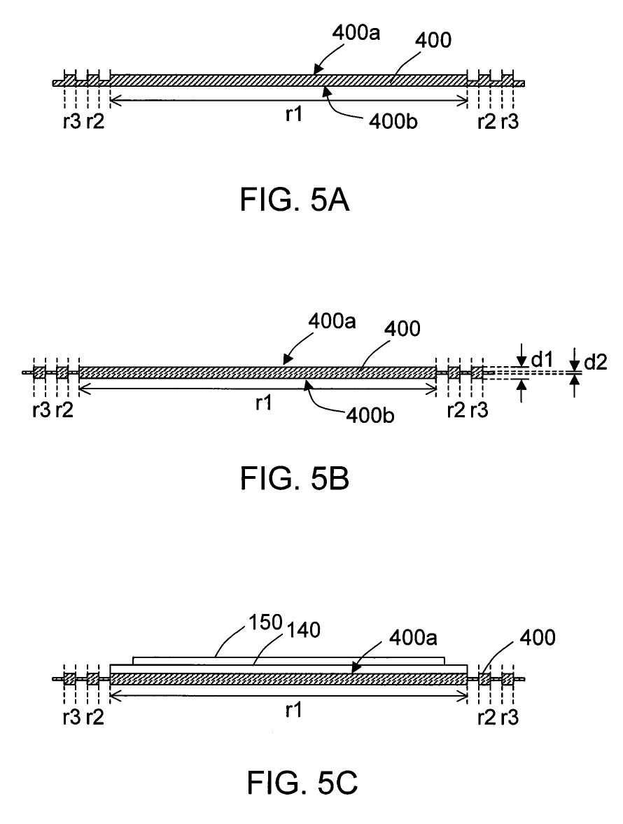

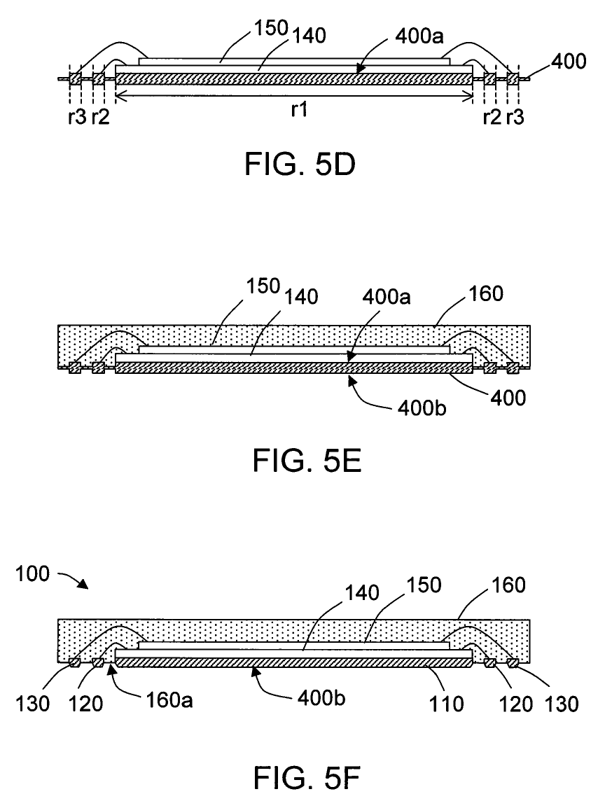

Also, according to the structure of the integrated circuit package 100 of the first embodiment, the integrated circuit package 100 can also be manufactured according to other manufacturing methods. Another method of manufacturing the integrated circuit package 100 of the first embodiment is exemplified below. Referring to FIGS. 5A˜5F, the method of the manufacturing of the integrated circuit package of the first embodiment are respectively shown. The manufacturing method, for example, includes the following steps.

Firstly, as indicated in FIG. 5A, a top surface 400a of the metal plate 400 is patterned. The present step is similar to the step of FIG. 4A and is not repeated here.

Next, as indicated in FIG. 5B, the bottom surface 400b of the metal plate 400 is patterned. In the present step, the bottom surface 400b of the metal plate 400 is etched according to a second pattern. The second pattern of the second embodiments substantially similar to the second pattern of the first pattern, such that the bottom surface 400b and the top surface of 400a of the metal plate 400 form a mirror-image symmetric structure, the metal plate 400 has a first thickness d1 in the first region r1, the second regions r2 and the third regions r3, and has a second thickness d2 in other regions.

Next, as indicated in FIG. 5C˜5E, the method includes the step of fixing the first die 120 and the second die 130, the step of electrically connecting the first die 120 and the second die 130 to the metal plate 400 by wire-bonding, and the step of forming a molding compound 160. These steps are similar to the steps illustrated in FIG. 4B˜4D and are not repeated here.

Then, as indicated in FIG. 5F, other part of the metal plate 400 (at least the part of metal plate 400 whose thickness is of the second thickness d2) is removed by etching the bottom surface 400b of the metal plate 400 for partly exposing the bottom surface 160b of the molding compound 160 to form the die pad 110, the first contact pads 120 and the second contact pads 130 which are electrically isolated from each other.

Lastly, at least one integrated circuit package 100 is formed by sawing.

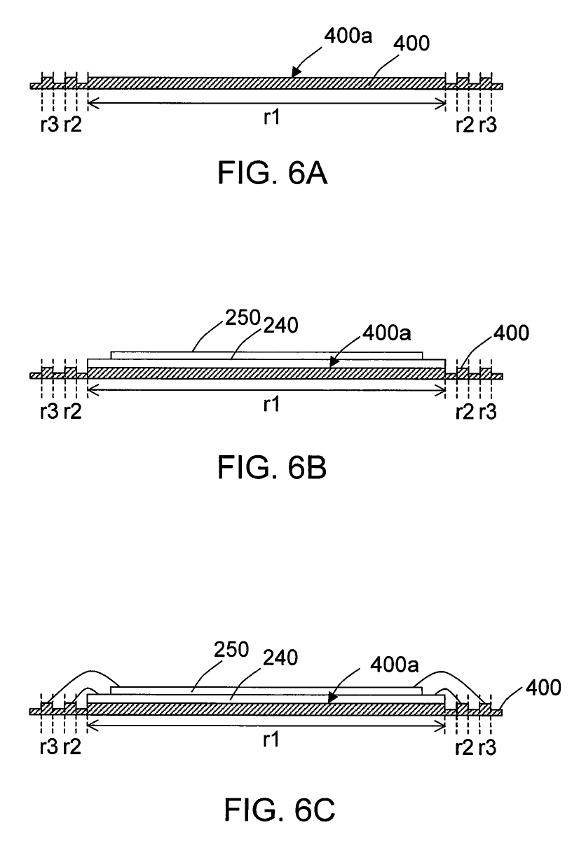

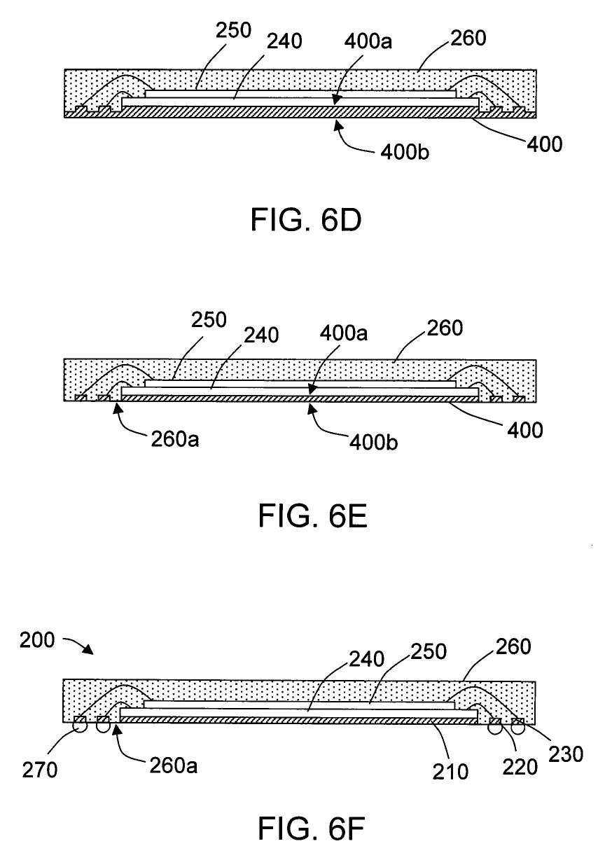

A method of manufacturing the integrated circuit package 200 of the second embodiment is disclosed below. Referring to FIGS. 6A˜6F, the method of the manufacturing of the integrated circuit package of the second embodiment are shown. The manufacturing method, for example, includes the following steps.

Firstly, as indicated in FIGS. 6A˜6D, the method includes the step of patterning the top surface 400a of the metal plate 400, the wire-bonding step, and the step of forming the molding compound 160. These steps are similar to the steps of FIGS. 4A˜4D and are not repeated here.

Next, as indicated in FIG. 6E, the bottom surface 400a of the metal plate 400 is removed by etching for forming the die pad 210, a plurality of first contact pads 220 and a plurality of second contact pads 230 which are electrically isolated from each other. The bottom of the die pad 210, the bottom of the first contact pads 220 and the bottom of the second contact pads 230 are substantially aligned with the bottom surface 260a of the molding compound 260.

Then, as indicated in FIG. 6F, a plurality of solder balls 270 is formed on the bottom of the first contact pads 220 and the bottom of the second contact pads 230.

After that, at least one integrated circuit package 100 is formed by sawing.

According to the manufacturing methods disclosed above, the die pad, the first contact pads, the second contact pads being electrically isolated from each other are formed by etching the bottom surface of the metal plate after the molding compound is formed. Thus, the manufacturing process is made simpler, and the manufacturing cost is further reduced.

In addition to the manufacturing methods disclosed above, U.S. Pat. No. 6,498,099 “Leadless Plastic Chip Carrier with Etch Back Pad Singulation” (by McLellan et al.) also illustrates another embodiment of the manufacturing method. The manufacturing method of the invention is applicable to any manufacturing processes or methods similar to U.S. Pat. No. 6,498,099 for manufacturing the package of the invention.

Apart from having excellent heat radiation and electrical properties, the integrated circuit package disclosed in the above embodiments of the invention further has stacked die structure such that the package can have more input/output solder pads, provide more functions but occupy smaller space. Besides, in the manufacturing method, the die pad, the first contact pads, the second contact pads being electrically isolated from each other are formed by etching the bottom surface of the metal plate after the molding compound is formed. Thus, the manufacturing process is made simpler, and the manufacturing cost is further reduced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An integrated circuit package, comprising:
a die pad;
a plurality of first contact pads and second contact pads both adjacent to at least one side of the die pad, wherein the first contact pads and the second contact pads are divided into two rows arranged along the at least one side of the die pad, the first contact pads are disposed in the inner row, the second contact pads are disposed in the outer row, and the die pad, each first contact pad and each second contact pad are electrically isolated from each other; a first die fixed on the die pad and electrically connected to the first contact pads by wire-bonding;
a second die fixed on the first die and electrically connected to the second contact pads by wire-bonding; and
a molding compound covering the second die, the first die, the die pad, the first contact pads and the second contact pads, wherein the bottom of the die pad, the bottom of the first contact pads and the bottom of the second contact pads are exposed at the bottom surface of the molding compound.

2. The integrated circuit package according to claim 1, wherein the bottom of the die pad, the bottom of the first contact pads and the bottom of the second contact pads are protruded from the bottom surface of the molding compound, and one side of each second contact pad is not aligned with the side wall of the molding compound.

3. The integrated circuit package according to claim 1, wherein the bottom of the die pad, the bottoms of the first contact pads and the bottoms of the second contact pads are substantially aligned with the bottom surface of the molding compound.

4. The integrated circuit package according to claim 3, further comprising a plurality of solder balls disposed on the bottom of the first contact pads and the bottom of the second contact pads.

5. The integrated circuit package according to claim 1, wherein the first contact pads and the second contact pads surround the die pad.

6. A method of manufacturing integrated circuit package, the method comprising:
(a) patterning a top surface of a metal plate so as to define a first region, a plurality of second regions and a plurality of third regions on the top surface, wherein the second regions and the third regions are both adjacent to at least one side of the first region, and are divided into two rows arranged along at least one side of the first region, the second regions are disposed in the inner row, and the third regions are disposed in the outer row;
(b) fixing a first die on the metal plate of the first region;
(c) fixing a second die on the first die;
(d) electrically connecting the first die to the metal plate of the second regions by wire-bonding;
(e) electrically connecting the second die to the metal plate of the third regions by wire-bonding;
(f) forming a molding compound on the top surface for covering the second die, the first die and the top surface; and
(g) etching at least a part of a bottom surface of the metal plate such that the metal plate respectively forms a die pad, a plurality of first contact pads and a plurality of second contact pads in the first region, the second regions and the third regions, wherein the die pad, the first contact pads and the second contact pads are electrically isolated from each other.

7. The manufacturing method according to claim 6, wherein after the step (g), the manufacturing method further comprises the step of forming a plurality of solder balls on the bottom of the first contact pads and the bottom of the second contact pads.

8. The manufacturing method according to claim 6, wherein in the step (a), the metal plate is etched according to a first pattern, such that the thickness of the patterned metal plate in the first region, the second regions and the third regions is larger than the thickness of the metal plate in other regions.

9. The manufacturing method according to claim 8, further comprising patterning the bottom surface of the metal plate.

10. The manufacturing method according to claim 9, wherein in the step of patterning the bottom surface of the metal plate, the bottom surface of the metal plate is etched according to a second pattern substantially the same with the first pattern, such that the bottom surface and the top surface of the metal plate form a mirror-image symmetric structure, the metal plate has a first thickness in the first region, the second regions and the third regions and has a second thickness in other regions, and the first thickness is larger than the second thickness.

11. The manufacturing method according to claim 10, wherein in the step (g), other part of the metal plate is removed for partly exposing the bottom surface of the molding compound, such that the metal plate respectively form the die pad, the first contact pads and the second contact pads being electrically isolated from each other in the first region, the second regions and the third regions.

12. The manufacturing method according to claim 6, wherein in the step (b) and the step (c), an epoxy resin is used for adhering the first die onto the metal plate in the first region and adhering the second die onto the first die, after the step (b) and the step (c), the manufacturing method further comprises solidifying the epoxy resin.

13. The manufacturing method according to claim 6, wherein in the step (f), a colloid is used for forming the molding compound, the manufacturing method further comprises solidifying the colloid.

14. The manufacturing method according to claim 6, wherein after the step (g), the manufacturing method further comprises:
sawing the metal plate for forming at least one integrated circuit package.
